(19) United States
(12) Patent Application Publication
(10) Pub. No.: US 2022/0301362 A1
(43) Pub. Date: Sep. 22, 2022

(54) BATTERY DIAGNOSTIC SYSTEM

(71) Applicant: TOYOTA JIDOSHA KABUSHIKI KAISHA, Toyota-shi (JP)

(72) Inventors: Hiroshi YAMASAKI, Nagoya-shi (JP); Yasuhide KURIMOTO, Kasugai-shi (JP)

(73) Assignee: TOYOTA JIDOSHA KABUSHIKI KAISHA, Toyota-shi (JP)

(21) Appl. No.: 17/690,108

(22) Filed: Mar. 9, 2022

(30) Foreign Application Priority Data
Mar. 18, 2021 (JP) 2021-044806

(51) Int. Cl. G07C 5/00; H02J 7/00; B60L 58/10; G01R 31/367; G01R 31/371; G06Q 30/02

(52) U.S. Cl. CPC G07C 5/008; H02J 7/0048; H02J 7/00032; B60L 58/10; G01R 31/367; G01R 31/371; G06Q 30/0208

(57) ABSTRACT

A battery diagnostic system includes a diagnostic server that diagnoses a battery mounted on a vehicle using battery information including usage information of the battery while the battery is mounted on the vehicle, and a diagnostic terminal that acquires the battery information from the vehicle, transmits the battery information to the diagnostic server, and receives a diagnoses result of the battery from the diagnostic server. When the diagnostic terminal transmits the battery information to the diagnostic server, the diagnostic terminal transmits information on whether a predetermined condition is satisfied together with the battery information to the diagnostic server. The diagnostic server accumulates the battery information when the predetermined condition is satisfied, and deletes the battery information after diagnosing the battery when the predetermined condition is not satisfied.

### CROSS-REFERENCE TO RELATED APPLICATION

This application claims priority to Japanese Patent Application No. 2021-044806 filed on Mar. 18, 2021, incorporated herein by reference in its entirety.

### BACKGROUND

### 1. Technical Field

The present disclosure relates to a battery diagnostic system, and more particularly to a battery diagnostic system including a diagnostic server and a diagnostic terminal.

### 2. Description of Related Art

Conventionally, as this type of technology, a technology including a first terminal device, a second terminal device, and a third terminal device has been proposed (see, for example, Japanese Unexamined Patent Application Publication No. 2000-207452 (JP 2000-207452 A)). The first terminal device is used by maintenance companies that transmit various data related to vehicles that has been acquired at at least one of repair and maintenance/inspection of customers' vehicles, via a communication line to register the various data as sales vehicle data. The second terminal device is used by used car purchasing companies that transmit various data related to purchase requests for used cars via a communication line to register the various data as purchase vehicle data. The third terminal device is used by information centers that register each of the sales vehicle data transmitted from the first terminal device and the purchase vehicle data transmitted from the second terminal device. In this technology, vehicle data that meets the conditions at the information center is provided to the customer as used car purchase information.

### SUMMARY

In the above system, the sales vehicle data regarding sales of the vehicle and the purchase vehicle data regarding purchase of the vehicle are transmitted and received. However, when the ownership of the battery information including usage information of the battery mounted on the vehicle while the battery is mounted on the vehicle is not transferred, accumulating the battery information without the permission of the owner may cause an issue. In hybrid vehicles and electric vehicles, diagnosing battery state is extremely important. In order to efficiently and appropriately diagnose the battery, it is effective to use the battery information of the battery. Further, when a large amount of battery information is accumulated and the battery is diagnosed based on the accumulated battery information, the battery can be diagnosed more appropriately. Therefore, it is desired to accumulate the battery information. However, since the battery information includes usage information while the battery is mounted on the vehicle, the battery information involves personal information. Thus, it is not preferable to accumulate the battery information without permission or transfer from the owner.

The main object of the battery diagnostic system of the present disclosure is to accumulate the battery information more effectively and more appropriately.

The battery diagnostic system of the present disclosure has adopted the following means in order to achieve the above-mentioned main object.

The battery diagnostic system of the present disclosure is a battery diagnostic system including a diagnostic server that diagnoses a battery mounted on a vehicle using battery information including usage information of the battery while the battery is mounted on the vehicle, and a diagnostic terminal that acquires the battery information from the vehicle, transmits the battery information to the diagnostic server, and receives a diagnoses result of the battery from the diagnostic server. When the diagnostic terminal transmits the battery information to the diagnostic server, the diagnostic terminal transmits information on whether a predetermined condition is satisfied together with the battery information to the diagnostic server. The diagnostic server accumulates the battery information when the predetermined condition is satisfied, and deletes the battery information after diagnosing the battery when the predetermined condition is not satisfied.

The battery diagnostic system of the present disclosure includes a diagnostic server that diagnoses a battery mounted on a vehicle using battery information including usage information of the battery while the battery is mounted on the vehicle, and a diagnostic terminal that acquires the battery information from the vehicle, transmits the battery information to the diagnostic server, and receives a diagnoses result of the battery from the diagnostic server. Further, when the diagnostic terminal transmits the battery information to the diagnostic server, the diagnostic terminal transmits information on whether a predetermined condition is satisfied together with the battery information to the diagnostic server. The diagnostic server accumulates the battery information when the predetermined condition is satisfied, and deletes the battery information after diagnosing the battery when the predetermined condition is not satisfied. As a result, the handling of the battery information can be changed according to the predetermined condition, and by appropriately determining the predetermined condition, the battery information can be effectively and more appropriately accumulated.

Here, the predetermined condition may be a condition performed by a decision of an owner of the battery. In this case, the predetermined condition may be either a condition of waiving an ownership of the battery information or a condition of permitting use and accumulation of the battery information.

In the battery diagnostic system of the present disclosure, the diagnostic terminal may output a provision of a predetermined service when the predetermined condition is satisfied. This makes it possible to facilitate satisfaction of the predetermined condition. In this case, the predetermined service may include any of a discount service for a diagnosis fee of the battery, a discount service for a battery replacement fee for the vehicle, and a service providing addition to an assessment amount of the vehicle.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a configuration diagram showing an outline of a configuration of a battery diagnostic system 20 as an embodiment of the present disclosure; and

FIG. 2 is an explanatory diagram showing a flow in a diagnostic process of a battery 12 in a diagnostic terminal 40 and a diagnostic server 30.

### DETAILED DESCRIPTION OF EMBODIMENTS

Next, a mode for carrying out the present disclosure will be described with reference to an embodiment.

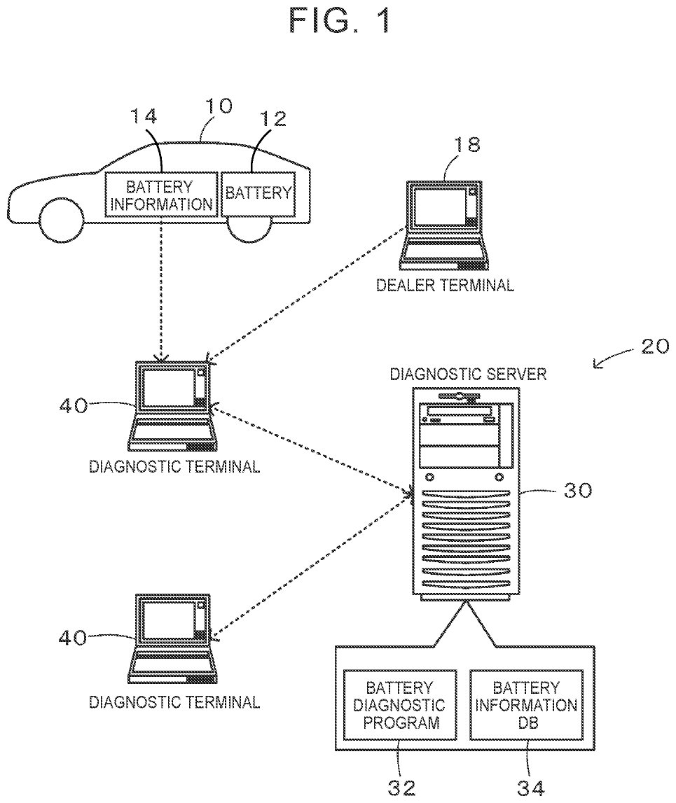

FIG. 1 is a configuration diagram showing an outline of a configuration of a battery diagnostic system 20 as an embodiment of the present disclosure. As shown in the figure, the battery diagnostic system 20 of the embodiment includes a diagnostic server 30 and a plurality of diagnostic terminals 40.

The diagnostic server 30 is configured as a general-purpose microcomputer centered on a central processing unit (CPU), and includes a read-only memory (ROM), a random access memory (RAM), a flash memory, a storage device, an input/output port, a communication port, and the like in addition to the CPU. The diagnostic server 30 includes a battery diagnostic program 32 for diagnosing the state of the battery and a battery information database 34 for accumulating battery information. Here, the battery information is information including usage information of a battery mounted on the vehicle while the battery is mounted on the vehicle, and includes, for example, a full charge capacity, a resistance, a voltage when the voltage exceeds the upper limit voltage and the number of times thereof, a voltage when the voltage falls below the lower limit voltage and the number of times thereof, a battery temperature during traveling and charging, a total discharge electricity amount, a charge/discharge current, a change amount of a state of charge SOC, a distribution of the state of charge SOC, the state of charge SOC during ignition off, a charge amount during charging, etc.

The diagnostic terminal 40 is configured as a general-purpose microcomputer centered on a CPU, and includes a ROM, a RAM, a flash memory, a storage device, an input/output port, a communication port, and the like in addition to the CPU. The diagnostic terminal 40 acquires battery information 14 of a battery 12 mounted on a vehicle 10 by wiredly or wirelessly communicating with the control device of the vehicle 10 and stores the battery information 14 in a RAM or the like. Further, the diagnostic terminal 40 acquires information on whether a predetermined condition is satisfied from a dealer terminal 18 installed at the dealer and stores the information in a RAM or the like. Here, the predetermined condition includes a condition of waiving the ownership of the battery information 14, a condition of permitting use and accumulation of the battery information 14, and the like, which are performed by the decision of the owner of the vehicle 10. For example, in the case of a transfer contract for the vehicle 10, the condition of transferring the battery information 14 for the battery mounted on the vehicle 10 or the condition of waiving the right thereof due to the transfer of the vehicle 10 is applicable, and in the case where the battery 12 of the vehicle 10 is replaced, the condition of transferring the battery information 14 for the battery 12 before the replacement or waiving the right thereof is applicable, or the condition of permitting the use and the accumulation of the battery information 14 is applicable.

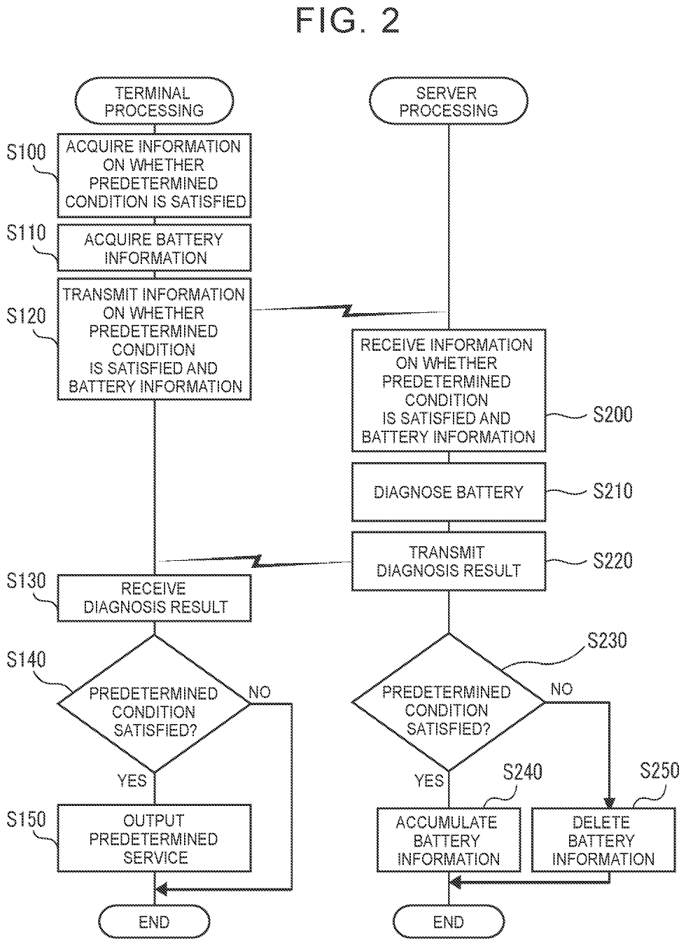

Next, the operation of the battery diagnostic system 20 configured in this way, particularly the operation at the time of battery diagnosis will be described. FIG. 2 is an explanatory diagram showing an example of terminal processing and server processing executed at the time of diagnosis of the battery 12 in the diagnostic terminal 40 and the diagnostic server 30.

In the diagnostic process, first, the diagnostic terminal 40 performs an acquisition process (step S100) of information on whether a predetermined condition is satisfied and an acquisition process (step S110) of the battery information 14 by the terminal processing. These acquisition processes have been described above. Either the acquisition process for the predetermined condition or the acquisition process of the battery information 14 may be performed first. Then, the acquired battery information 14 and the acquired information on whether the predetermined condition is satisfied are transmitted to the diagnostic server 30 (step S120).

When the diagnostic terminal 40 transmits the battery information 14 and the information on whether the predetermined condition is satisfied, the diagnostic server 30 receives the battery information 14 and the information on whether the predetermined condition is satisfied (step S200), and diagnoses the battery 12 using the received battery information 14 (step S210). The diagnosis of the battery can be performed by various methods, and since the battery diagnosis method is not the main subject of the present disclosure, a detailed description thereof will be omitted. When the diagnosis of the battery 12 is completed, the diagnosis result is transmitted to the diagnostic terminal 40 (step S220). Then, it is determined whether the predetermined condition is satisfied (step S230), and when it is determined that the predetermined condition is satisfied, the battery information 14 is accumulated in the battery information database 34 (step S240), and the server processing is terminated. On the other hand, when it is determined in step S230 that the predetermined condition is not satisfied, the received battery information 14 is deleted (step S250), and the server processing is terminated. As a result, it is possible to suppress any inconvenience that may occur due to accumulating or storing the battery information 14 even though the predetermined condition is not satisfied.

When the diagnosis result is transmitted from the diagnostic server 30, the diagnostic terminal 40 receives the diagnosis result (step S130). Then, it is determined whether the predetermined condition is satisfied (step S140), and when it is determined that the predetermined condition is satisfied, the predetermined service is output to the display of the diagnostic terminal 40 or the like (step S150), and the terminal processing is terminated. Examples of the predetermined service include a discount service for the diagnosis fee of the battery 12, a discount service for the replacement fee of the battery 12 for the vehicle, and a service providing addition to the assessment amount of the vehicle in the case of transfer of the vehicle. On the other hand, when it is determined in step S140 that the predetermined condition is not satisfied, the terminal processing is terminated without outputting the predetermined service. As a result, it is possible to promote the owner to waive the ownership of the battery information 14 and permit the use and the accumulation of the battery information 14, which makes it possible to accumulate more battery information. Since a large amount of battery information is often used to create a battery diagnostic program, it is possible to create a more appropriate diagnostic program by accumulating more battery information.

The battery diagnostic system 20 of the embodiment described above acquires, from the diagnostic terminal 40, the information on whether the condition of waiving the ownership of the battery information 14 and the condition of permitting the use and the accumulation of the battery information 14 performed by the decision of the owner of the battery information 14 are satisfied. Then, the diagnostic terminal 40 transmits the battery information 14 acquired from the vehicle 10 and the information on whether the predetermined condition is satisfied to the diagnostic server 30. When the diagnostic server 30 determines that the predetermined condition is not satisfied after diagnosing the battery 12, the diagnostic server 30 deletes the battery information 14. As a result, it is possible to suppress any inconvenience that may occur due to accumulating or storing the battery information 14 even though the predetermined condition is not satisfied. Further, when the predetermined condition is satisfied, the diagnostic terminal 40 outputs a predetermined service such as a discount service for the diagnosis fee, a discount service for the battery replacement fee, and a service providing addition to the vehicle assessment amount. As a result, it is possible to promote the owner to waive the ownership of the battery information 14 and permit the use and the accumulation of the battery information 14, which makes it possible to accumulate more battery information. This makes it possible to create a more appropriate diagnostic program using more battery information. As a result, the battery information can be accumulated more effectively and more appropriately.

In the battery diagnostic system 20 of the embodiment, the diagnostic terminal 40 acquires the information on whether the predetermined condition is satisfied from the dealer terminal 18 installed at the dealer. However, the information on whether the predetermined condition is satisfied may be acquired by directly inputting the information to the diagnostic terminal 40.

In the battery diagnostic system 20 of the embodiment, the predetermined service is a discount service for the diagnosis fee of the battery 12, a discount service for the replacement fee of the battery 12 for the vehicle, a service providing addition to the assessment amount of the vehicle in the case of transfer of the vehicle, and the like. However, the predetermined service may be services other than those described above.

The correspondence between the main elements of the embodiment and the main elements of the disclosure described in SUMMARY will be described. In the embodiment, the vehicle 10 corresponds to the “vehicle”, the battery 12 corresponds to the “battery”, the battery information 14 corresponds to the “battery information”, the diagnostic server 30 corresponds to the “diagnostic server”, the diagnostic terminal 40 corresponds to the “diagnostic terminal”, and the battery diagnostic system 20 corresponds to the “battery diagnostic system”.

As for the correspondence between the main elements of the embodiment and the main elements of the disclosure described in SUMMARY, since the embodiment is an example for specifically describing a mode for carrying out the disclosure described in SUMMARY, the embodiment does not limit the elements of the disclosure described in SUMMARY. In other words, the interpretation of the disclosure described in SUMMARY should be performed based on the description in SUMMARY, and the embodiment is merely a specific example of the disclosure described in SUMMARY.

Although a mode for carrying out the present disclosure has been described above with reference to the embodiment, the present disclosure is not limited to the embodiment, and it goes without saying that the present disclosure can be carried out in various modes without departing from the gist of the present disclosure.

The present disclosure can be used in the manufacturing industry of a battery diagnostic system and the like.

What is claimed is:

1. A battery diagnostic system including a diagnostic server that diagnoses a battery mounted on a vehicle using battery information including usage information of the battery while the battery is mounted on the vehicle, and a diagnostic terminal that acquires the battery information from the vehicle, transmits the battery information to the diagnostic server, and receives a diagnoses result of the battery from the diagnostic server, wherein:
when the diagnostic terminal transmits the battery information to the diagnostic server, the diagnostic terminal transmits information on whether a predetermined condition is satisfied together with the battery information to the diagnostic server; and
the diagnostic server accumulates the battery information when the predetermined condition is satisfied, and deletes the battery information after diagnosing the battery when the predetermined condition is not satisfied.

2. The battery diagnostic system according to claim 1, wherein the predetermined condition is a condition performed by a decision of an owner of the battery.

3. The battery diagnostic system according to claim 2, wherein the predetermined condition is either a condition of waiving an ownership of the battery information or a condition of permitting use and accumulation of the battery information.

4. The battery diagnostic system according to claim 1, wherein the diagnostic terminal outputs a provision of a predetermined service when the predetermined condition is satisfied.

5. The battery diagnostic system according to claim 4, wherein the predetermined service includes any of a discount service for a diagnosis fee of the battery, a discount service for a battery replacement fee for the vehicle, and a service providing addition to an assessment amount of the vehicle.
